(19) United States
(12) Patent Application Publication
(10) Pub. No.: US 2008/0129565 A1
(43) Pub. Date: Jun. 5, 2008

(54) Apparatus for and method of sigma-delta modulation

(75) Inventors: Hans Gustat, Heidesee/OT Prieros (DE); Pylyp Ostrovskyy, Frankfurt (DE)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(73) Assignees: IHP GmbH - Innovations for High Performance Microelectronics/; Institut fur innovative Mikroelektronik

(21) Appl. No.: 11/985,334

(22) Filed: Nov. 14, 2007

(30) Foreign Application Priority Data
Nov. 17, 2006 (DE) 10 2006 054 776.4

(51) Int. Cl. H03M 3/00

(52) U.S. Cl. 341/143

(57) ABSTRACT

The invention concerns an electronic circuit comprising a sigma-delta modulator (200) and a clock generator (210) which outputs a clock signal (clk(t)) which is suitable for clock control of the sigma-delta modulator (200), wherein the clock generator is adapted to set the clock rate of the clock signal (clk(t)) variably in dependence on an instantaneous frequency of the input signal (x(t)).

### CROSS REFERENCE TO RELATED APPLICATIONS

Reference is made to and priority claimed from German patent application Ser. No. 10 2006 054 776.4, filed Nov. 17, 2006.

### BACKGROUND OF THE INVENTION

1. Technical Field

The invention concerns an apparatus for and a method of sigma-delta modulation, in particular an electronic circuit for sigma-delta modulation.

2. Discussion of Related Art

Sigma-delta modulators (SDMs) are used in a large number of applications and usually serve for analog-digital conversion (A/D conversion) of electrical signals. Sigma-delta modulators (also referred to as delta-sigma modulators) convert analog time-continuous and value-continuous input signals into digital time-discrete and value-discrete output signals. They usually consist of a summing or subtracting member, a loop filter, an A/D converter and a digital-analog converter (D/A converter). The specified components are arranged in a closed loop, within which the digital output signal is converted back into an analog signal again and deducted from the input signal. That affords from the input to the output of the modulator given transfer functions which form the power density spectrum from various input to output points of the modulator in a characteristic fashion. Thus there is a so-called signal transfer function (STF) between the signal input of the useful signal and there is the so-called noise transfer function (NTF) between the A/D converter, to the output. The aim of the modulator loop is to transfer the input signal to the output with as little disturbance as possible while the noise or interference contributions of the modulator, in relation to the output, should be as low as possible. In many applications a 1-bit A/D converter (comparator) is used. That A/D converter (like also other parts of the circuit which are clock controlled) operates with a markedly higher sampling rate (oversampling) than the signal bandwidth of the input signal at least requires on the basis of the sampling theorem. By virtue of oversampling and the configuration of the STF and the NTF it is possible for example to use a 1-bit A/D converter and nonetheless achieve a very high level of resolution or a very high dynamic range of the sigma-delta A/D converter. Besides the sigma-delta modulator, a complete sigma-delta analog-digital converter also requires a downstream-connected filter (for example a decimator) which suppresses the interfering noise components which are outside the useful range and if desired also converts the flow of sampling values at a high sampling rate into a flow of wider bit words with a lower sampling rate (for example at the Nyquist frequency). The mode of operation for dimensioning and assembling the components, in particular the degree of oversampling, and the required properties of the loop filter in order to achieve a correspondingly high dynamic range have long been known. A conventional SDM operates with a constant clock (that is to say at a constant frequency) for the A/D converter and for the D/A converter. Admittedly in principle a distinction is drawn between continuous and time-discrete sigma-delta modulators but that difference only concerns the loop filter which is constructed either in time-continuous mode or clock-controlled mode (for example in the form of what is referred to as a switched capacitor filter). At least the A/D converter which is contained in the loop of the sigma-delta modulator must however be clock-controlled; typically however the D/A converter is also clock-controlled. It is possible to use z-transformation for modeling of the transfer functions of the system. A usual representation of the transfer function of the loop filter is then H(z).

Sigma-delta modulators, based on their order and the sampling rate, under some circumstances cause a very high degree of noise suppression in the signal bands of the useful signal. The noise transfer function can have a high-pass characteristic or also a band-pass characteristic or band-rejection characteristic. With a correct choice of the noise and signal transfer functions, the noise of the sigma-delta modulator, in particular the quantization noise of the A/D converter in the loop of the modulator, can be suppressed at certain frequencies which are in a fixed relationship to the clock rate of the sigma-delta modulator. Narrow-band ranges in which local minima of the noise occur are referred to as notches. The sigma-delta modulator is then usually dimensioned and operated in such a fashion that such a noise minimum coincides with the signal band of the input or useful signal. Ideally then the middle of the frequency band of the input signal is within such a notch. An aim of sigma-delta modulation is to achieve as small amount of noise as possible in the signal band. If the bandwidth of the input signal rises or the frequencies of the input signal vary, noise components also occur in the signal range of the input signal. The attainable signal-to-noise ratio or the resolution or the dynamic range of the sigma-delta modulator suffers therefrom.

In order to achieve a low level of noise and a greater bandwidth for the useful signal it is possible to modify the properties of the loop filter of the modulator. A known measure for example involves raising the order of the loop filter. That makes it possible to achieve a noise transfer function which suppresses the noise components in the signal band to a progressively greater degree, within increasing order. There is however the disadvantage that sigma-delta modulators can become unstable at an order which is greater than 2. In addition the power consumption of the modulators increases with a rising order. In the case of sigma-delta modulators of fixed, low (for example first or second) order, the signal-to-noise ratio which can be achieved is to be improved only by an increase in oversampling. In other words, in the conventional sigma-delta modulator, the ratio of the width to the depth of the desired minimum is limited in the power density spectrum of the noise signal and can only be improved by an increase in the sampling rate (oversampling). An increase in the sampling rate or oversampling however entails an increase in the power loss. There is thus a conflict between power consumption, technology parameters, order and oversampling as well as the attainable level of performance of a sigma-delta modulator. In order to do justice to various input signals it is therefore known for example to switch over between two fixed clock rates, depending on the amplitude of the respective input signal. In that case, two fixed clock rates are applied to the sigma-delta modulator.

### DISCLOSURE OF INVENTION

The object of the present invention is to provide a sigma-delta modulator, which for variable input signals, has a lower level of noise than conventional sigma-delta modulators.

In accordance with an advantageous aspect of the present invention, the object is attained by an electronic circuit comprising a sigma-delta modulator and a clock generator which is adapted to output a clock signal which is suitable for clock control of the sigma-delta modulator, wherein the clock generator is additionally adapted to set the clock rate of the clock signal variably in dependence on an instantaneous frequency of the input signal. In that respect, an input signal (for example a time-continuous and value-continuous input signal) is temporarily viewed as a quasi-periodic signal. That is possible to a very good approximation in many applications. Frequently the input signal is a signal (for example a sine signal) which is modulated in respect of frequency, phase and amplitude. Thus, for example in the case of modulation methods of wired or wireless transmission of data, a high carrier frequency is frequently modulated within a comparatively narrow band. The present invention can be used to particular advantage for uses of that kind. In such a case it is possible at any moment in time to associate with the input signal a frequency which corresponds to the reciprocal value of the instantaneous period duration of the oscillation which has just occurred. For short time portions (for example two period durations) the input signal can then be represented in an adequate approximation by a signal at a fixed frequency. The input signal is then deemed to be quasi-periodic for that period of time. In the most frequent case of a sine signal, the signal is then to be viewed as quasi-sinusoidal. Subsequent periods of the sine signal do not differ from the currently prevailing period in the qualitative curve shape (which for example is always a sine curve), but only in frequency and amplitude. In accordance with the invention now a clock signal is produced for the sigma-delta modulator, which is produced in response to the, for example, comparatively slight frequency shift or phase shift of the input signal. A suitable variation in the clock rate of the clock signal makes it possible, for example, to displace a local minimum in respect of the noise power density in the noise transfer function (NTF) of the sigma-delta modulator so that the frequency or frequency band of the input signal always optimally coincides with the noise minimum. Advantageously, the sigma-delta modulator and the clock generator can be provided in an integrated circuit. In accordance with the invention, the terms “variably” and “in dependence on” an instantaneous frequency of the input signal are to be interpreted as meaning that the clock rate of the sigma-delta modulator is adapted in such a way that the noise minimum of the noise transfer function of the sigma-delta modulator advantageously matches the altered instantaneous frequency of the input signal. The time relationships required for that purpose can vary depending on the respective application involved but can be ascertained by the person skilled in the art without involving major complication and expenditure from the instantaneous frequency, which is to be expected, of the input signal, the shift to be expected or the time progress in respect of the shift and the average duration for which a given frequency of the input signal is maintained. In addition, consideration is to be given to the architecture of the modulator as well as the sampling rate or the oversampling rate of the modulator.

In accordance with a further advantageous aspect of the present invention, the clock generator includes a clock multiplication circuit which detects the instantaneous frequency of the input signal and produces the clock signal for the sigma-delta modulator by multiplication of the detected frequency of the input signal. That aspect of the present invention takes account of the requirement that the sigma-delta modulator is an oversampling modulator, for the function of which a suitable relationship between the frequency of the input signal and the oversampling rate is desirable. In particular in that respect account is to be taken of the fact that there is a characteristic relationship between the change in the clock rate of the modulator and adaptation of the noise transfer function, that is to say, for example, the local minimum in the noise transfer function (notch etc.) and the shift in respect of phase and frequency of the input signal. That relationship is connected to the degree of oversampling and the order and transfer characteristic of the modulator.

In accordance with an advantageous aspect of the present invention the clock generator is adapted to set the clock rate of the clock signal variably from a digital data stream which represents the instantaneous frequency of the input signal. Accordingly, the clock rate of the sigma-delta modulator can be set to the instantaneous frequency of the input signal with a suitable clock generator in the same manner as discussed hereinbefore, wherein in accordance with this aspect of the invention the required information is generated from a digital data stream.

In accordance with another advantageous aspect of the invention, the digital data stream which contains the information about the instantaneous frequency of the input signal can contain in particular the period duration and the amplitude of the input signal as digital information. In that respect the present invention embraces a digital data stream which still has to be evaluated to ascertain the required items of information but also a digital data stream which directly contains the required information. The information about the instantaneous frequency is then appropriately in the period duration of the input signal.

In accordance with a further advantageous aspect of the invention there is provided a converter circuit which converts the analog input signal of the modulator into a digital data stream before it is applied to the sigma-delta modulator. Accordingly in accordance with the invention, consideration is advantageously given to the fact that, for example, a simple periodic input signal can be easily converted into a digital signal in order then to ascertain the instantaneous frequency. By way of the example it is possible for that purpose to use comparators or limiter circuits which detect the zero-crossings of the input signal and output a corresponding square-wave signal. In accordance with a further advantageous configuration the digital data stream defined in that way then contains explicit information about the instantaneous frequency of the input signal. That digital information can be very easily used to adapt the lock rate in accordance with the instantaneous frequency.

In accordance with a further advantageous aspect of the invention, the clock generator is so designed that in addition to the periodic clock signal a clock event is inserted upon a zero-crossing of the input signal. In particular a clock event is inserted outside the clock period to be expected. In accordance with this aspect of the present invention, a clock event includes a rising or a falling clock edge or rising and falling clock edges. In accordance with this advantageous aspect of the invention, the sigma-delta modulator is therefore admittedly operated irregularly in given intervals between the clocks (that is to say derivation of the instantaneous frequency is not steady), but the arrangement ensures that the signal is sampled with fewer errors than in the case of conventional sigma-delta modulators. The reason for this is that, at each additionally generated clock, the sampling error is reduced, which, in the proximity of the zero position, acts similarly to oversampling. That means that the quasi-periodic components of the input signal are taken into consideration in an improved form in the sampling procedure and the noise of the sigma-delta modulator in the proximity of the multiple of the instantaneous frequency of the input signal becomes less.

In accordance with a further advantageous configuration for each piece-wise quasi-periodic portion of the input signal, but at least for half a period, the period duration and the amplitude of the input signal are digitally represented. The input signal is then expressed as a series of half-periods of respectively constant period duration and amplitude. That also simplifies the use of the present invention for certain classes of input signals.

In accordance with a further advantageous aspect of the invention the clock generator includes a plurality of delay elements which are arranged as a ring oscillator, wherein the delays of the delay elements are adjustable in response to the instantaneous frequency of the input signal and the clock signal for the sigma-delta modulator is derived from the oscillator frequency of the ring oscillator. Concealed behind that aspect of the present invention is a further advantageous configuration which permits simple adaptation of the clock rate by adaptation of the delays of the ring oscillator.

In accordance with a further aspect of the invention, the clock generator includes a clock divider which produces the clock for the sigma-delta modulator from a constant clock by division by a variable rational number, wherein the clock divider is determined in response to the instantaneous frequency of the input signal. That advantageous configuration permits fine fractional adaptation of the clock rate, which can produce an improvement in the performance of the SDM.

Behind the invention there is inter alia the realization that adapting the clock frequency of the modulator to the instantaneous frequency of the quasi-steady input signal provides that a specific noise minimum of the spectrum of the SDM is shifted simultaneously with the change in the instantaneous frequency of the input signal so that the SDM has its noise minimum substantially closer to the instantaneous frequency than in the conventional SDM. In that way the SDM can flexibly deal with altered input signals and has a lower level of inherent noise for the respective input signal than a conventional SDM of the same order. Considered in a different way, the order of a conventional SDM can be reduced with this invention while nonetheless achieving equal or better noise performance, in relation to the input signal. That makes it possible to save on chip area and power, which is of great use in particular for mobile applications.

It is to be noted that, as sampling no longer takes place at a constant frequency, z-transformation can no longer be readily used. The loop filter can then no longer be described as usual by H(z). It is however not out of the question to nonetheless approximately use a z-transformation for this system, for example by definition of a temporarily constant frequency so that the z-transformation approximately applies. At another moment in time for an altered instantaneous frequency in respect of the input signal, that z-transformed frequency is superceded by a z-transformation with a different time base. The smaller the signal bandwidth in relation to the carrier frequency, the correspondingly better does that approximation apply and at very small bandwidths relative to the carrier frequency, even a constant transfer function H(z), as in conventional SDMs, could be an adequate approximation.

In accordance with the invention the object is also attained by a method of operating a sigma-delta modulator comprising the steps: determining the instantaneous frequency of an input signal of the sigma-delta modulator and producing a clock signal for the sigma-delta modulator at a clock rate which is variably established in dependence on the instantaneous frequency of the input signal.

Furthermore, the object is also attained by a method of designing an integrated circuit comprising the steps: arranging a sigma-delta modulator on an integrated circuit, arranging a clock generator circuit for generating a clock signal on the integrated circuit; and designing the clock generator circuit in such a way that in operation it generates a clock signal for the sigma-delta modulator which is at a clock rate which is variably adapted in response to the instantaneous input frequency of the input signal.

### BRIEF DESCRIPTION OF THE DRAWINGS

Further advantageous method steps of the aforementioned methods correspond to the foregoing design configurations of the electronic circuit in accordance with the advantageous aspects of the present invention.

The embodiments by way of example of the present invention are described hereinafter with reference to the accompanying Figures in which:

FIG. 1 shows a simplified block diagram of a conventional sigma-delta modulator,

FIG. 2 shows a simplified block diagram of an embodiment in accordance with the present invention, and

FIG. 3 shows the power density spectrum of a conventional sigma-delta modulator with a band-pass characteristic.

### DETAILED DESCRIPTION

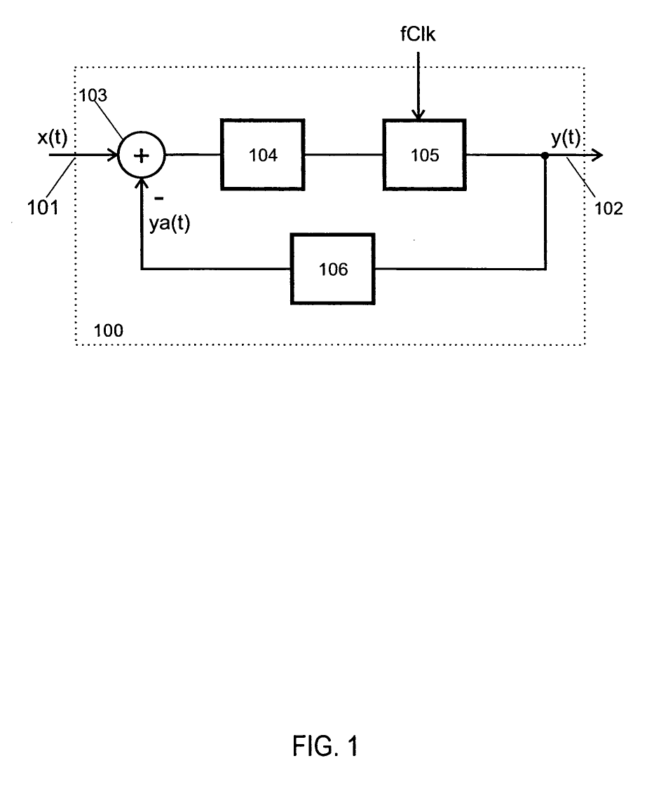

FIG. 1 shows a simplified block diagram of a conventional sigma-delta modulator 100. The input signal x(t) at the point 101 goes to a summing member 103 which subtracts from the input signal x(t) the output signal y(t) which is present at the node 102. The sum or difference formed in that way goes to circuit components 104 which form a transfer function H(z). After filtering of the signal with the transfer function H(z) in the block 104, it is converted into a digital signal by an analog-digital converter 105 with the clock rate fClk. That causes quantization noise to be added to the useful signal. The sampling rate fClk of the analog-digital converter 105 is kept constant. The output signal y(t) is converted into a, for example, value-continuous or value- and time-continuous signal ya(t) again by way of the digital-analog converter 106 and subtracted from the input signal x(t) in the summing member 103, as described hereinbefore. That implements a modulator loop. That provides for specific shaping of the power density spectrum between the input 101 and the output 102 and the quantization noise of the analog-digital converter 105 with respect to the output 102. Those relationships are generally known. The sigma-delta modulator 100 is adapted to given input signals x(t) by the selection of the transfer function H(z) in the block 104. Transfer functions with a low-pass characteristic for the input signal x(t) and a high-pass characteristic for the quantization noise with respect to the output 102 are typical. There also exist transfer functions for the quantization noise with a band-pass or a band-rejection characteristic so that a minimum in respect of the quantization noise (notch) occurs at a specific frequency for the input signal x(t).

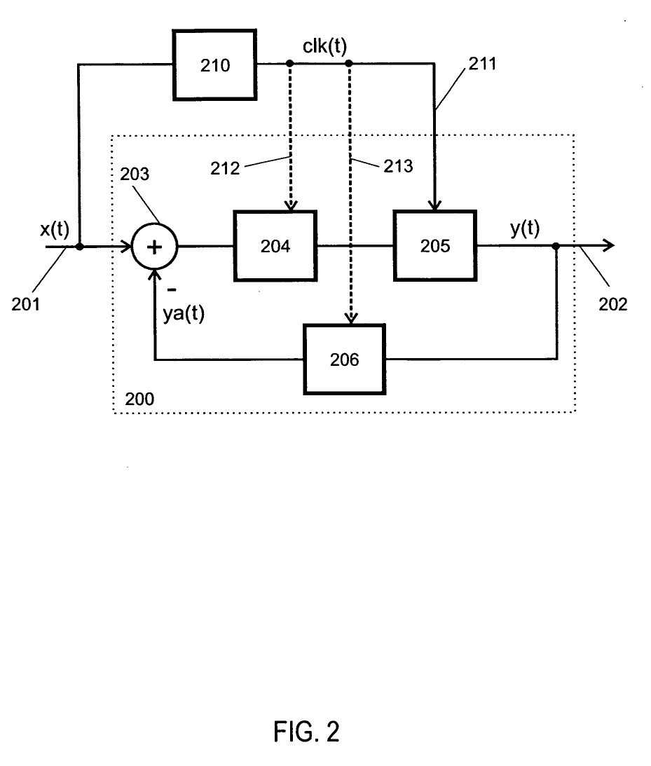

FIG. 2 shows a simplified block diagram of an embodiment by way of example of the present invention. In accordance therewith the sigma-delta modulator 200 is supplemented by a clock generator 210. The input signal x(t) which is applied at the input 201 is again summed in the summing member 203 with the output signal y(t) which is converted back by way of the digital-analog converter 206 and which occurs at the output 202 or the output signal ya(t) is subtracted from the input signal x(t). The difference signal produced in that way is filtered in the block 204 with a transfer function H(t) which is now applied to an analog-digital converter 205, the output of which in turn outputs the output signal y(t) to the node 202. Unlike the conventional design configuration of the sigma-delta modulator, the analog-digital converter 205 is now clock-controlled with a variable clock clk(t) at the input 211. That variable clock is generated in the clock generator 210. The clock generator 210 generates the clock clk(t) based on the input signal x(t). In accordance with advantageous configurations of the invention, the instantaneous frequency of the input signal x(t) is taken into consideration and the clock rate from the clock generator flexibly adapted to the variable clock rate. Thus—unlike the situation in FIG. 1—the clock clk(t) is not at a constant frequency but is a time-variable signal which is only temporarily periodic or also not periodic at all. Those properties depend on the configuration of the input signal x(t). The variable clock clk(t) can also optionally be used for the filter 204 or the D/A converter 206. That is appropriate when those components are clock-controlled and are to run synchronously with the A/D converter. In that case the clock clk(t) is also passed to the filter 204 by means of the line 212 and to the D/A converter 206 by means of the line 213.

A modification which is also possible to the example according to the invention shown in FIG. 2 provides that it is not the A/D converter 205 but one of the other components in the signal path of the feedback loop, for example the D/A converter 206 or the block 204, that is clock-controlled with the variable clock x(t). In that case also the variable clock x(t) then acts on the characteristic and the position of the noise minima of the SDM. In that case the A/D converter 205 operates either without its own clock or with a further clock which is not shown in FIG. 2 and which, for example, is a fixed clock at a substantially higher frequency than that of the clock clk(t).

In regard to the procedure of the clock generator 210 in accordance with the invention there are provided various configurations which are described hereinafter. An advantageous embodiment of the invention provides that the variable frequency fClk of the clock clk(t) of the SDM is produced as a multiple of the instantaneous and time-variable frequency f(t). In that case the variable frequency f(t) is the instantaneous frequency of the input signal x(t). A number of clock multiplier circuits are known for clock multiplication purposes. By way of example it is possible to use a train of clock doublers. Each clock doubler can operate for example in such a way that it rectifies the signal, for example a sine or triangular signal at its input and displaces the offset of the result in such a way that zero-crossings occur at the output at double the frequency to the input. If a comparator is connected downstream of that clock doubler, the result is a square-wave signal, which is highly suitable for a clock. In addition, a pulse shaper of integrating character can in turn be connected downstream of that comparator so that triangular signals of the same frequency as the square-wave signals occur at the output thereof. They in turn can be applied to a subsequent clock doubler which rectifies those signals so that the result is double frequency, and so forth. In that fashion k doubling stages produces an output signal at a frequency fClk(t)=2^{k}·f(t) and the SDM operates at a variable sampling rate of 2^{k}·f(t).

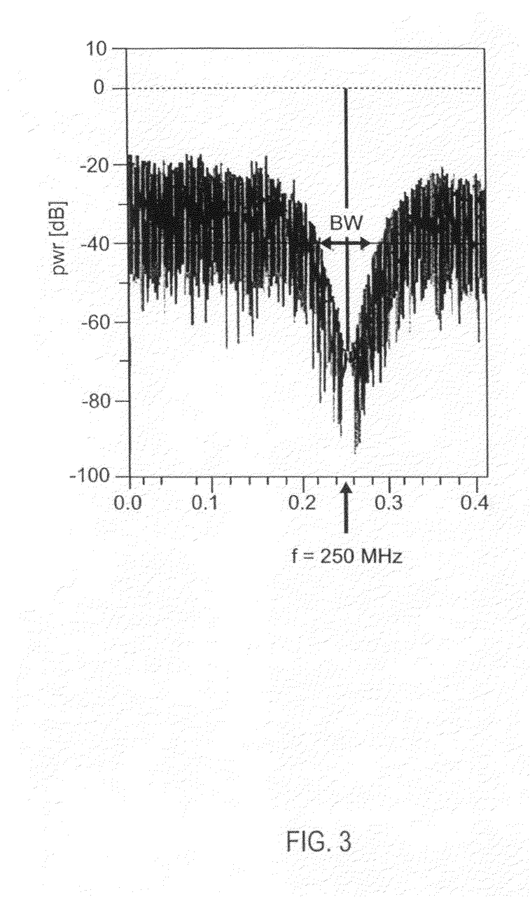

The resulting noise spectrum can be similar from the point of view of shape to that of a conventional SDM, as is shown in FIG. 3, as FIG. 3 involves an oversampling of 4 (fClk=1 GHz, f=250 MHz). It is only in the case of the SDM according to the invention, because of the variable clock control, that the location of the noise minimum is displaced on the frequency axis depending on the respective instantaneous value of f(t) which for example can depend on the degree of modulation of x(t), more or less slightly on the frequency scale towards the left or right.

In accordance with another embodiment of the invention the clock of the modulator clk(t) is basically generated from a fixed frequency fClk_a=const., in which case however a clock is additionally generated for clk(t) at zero-crossings of x(t). That means that the SDM operates with abruptly irregularly sized intervals between the clocks (or the derivation of the instantaneous frequency fClk(t) is not steady). This arrangement nonetheless ensures that the signal is sampled with fewer errors than in the case of conventional SDMs, for the sampling error is reduced at each additionally generated clock at clk(t). That measure acts similarly to oversampling in the proximity of the zero locations. That takes account of the quasi-periodic components of x(t) in the sampling procedure and the noise of the SDM in the proximity of the multiple of the instantaneous frequency f(t) is less.

A further embodiment of the invention is based on the fact that x(t) is no longer applied as usual in the form of an analog value to the SDM but in the form of a digital data stream, preferably already entailing explicit information about the instantaneous frequency f(t). A simple case in that respect is that, for each portion-wise periodic part of x(t) or for each part of x(t) which can be approximated by a portion of a periodic function, for example in the case of a sine function at least for a half-wave, the period duration and amplitude is specified. The function x(t) is then expressed as a series of half-waves or longer periodic sequences of respectively constant period duration and amplitude. Then clk(t) can be generated by way of the digital value of f(t), for example by digital setting of the delay of elements of a delay line which closed as a ring acts as an oscillator and generates the clock clk(t).

In accordance with a further configuration the arrangement does not involve a train of delay elements (delay line) but a clock divider which produces the clock clk(t) from a fixed master clock clk0(t) by division by a rational number. The division of clocks with fractions can be achieved by the integral part of the quotient being produced and an additional clock delay being added for the fractioned part. That principle is also used inter alia in conventional fractional N-phase lock loops.

FIG. 3 shows by way of example a spectral distribution of the power density of the quantization noise of a conventional SDM for a specific choice of the signal transfer function and the noise transfer function respectively for a given H(z). Standardized frequency is plotted on the X-axis and the power density pwr in dB is plotted on the Y-axis. The view is intended to illustrate a signal and noise transfer characteristic in respect of which the quantization noise has a minimum in a given frequency range (band BW). Ideally, the spectral signal components of the useful signal (that is to say of the input signal x(t)) lie in that band. That is indicated in FIG. 3 by a peak which projects out of the noise minimum (trough). The useful signal is for example at 250 MHz. The local minimum of the noise is also there. Subsequent filtering (for example in a decimator) of the illustrated spectrum provides that the spectral components of the quantization noise, which lie outside the useful signal band, are suppressed so that a desired signal-to-noise ratio is achieved. The subsequent processing step involves digital filtering which, as mentioned above, is implemented for example by means of what are referred to as decimators. If the frequency or the spectral components of the input signal are not in a region in which the quantization noise involves a minimum, the signal-to-noise ratio or the attainable dynamic range of the sigma-delta modulator is worsened.

The position of the noise minimum is altered by an SDM according to the invention, for example insofar as it is entrained with the frequency of the input signal by clock multiplication. With a sufficiently slow change in the frequency of the input signal the form shown by way of example in FIG. 3 for the minimum of the quantization noise of a conventional SDM can be qualitatively maintained, but in that case there is then a shift with the clock frequency which now variable instead of being fixed. That new shape of the quantization noise of an SDM according to the invention could approximately be described with a spectrum as shown in FIG. 3 if, instead of the fixed frequency as in FIG. 3, a frequency which is standardized to the input signal is used for the X-axis.

What is claimed is:

1. An electronic circuit comprising:
a sigma-delta modulator (200), and
a clock generator (210) adapted to output a clock signal (clk(t)) which is suitable for clock control of the sigma-delta modulator (200), wherein the clock generator is additionally adapted to set the clock rate of the clock signal (clk(t)) variably in dependence on an instantaneous frequency of the input signal (x(t)).

2. An electronic circuit as set forth in claim 1, comprising:
a clock multiplication circuit which detects the instantaneous frequency of the input signal and produces the clock signal (clk(t)) for the sigma-delta modulator (200) by multiplication of the detected frequency of the input signal (x(t)).

3. An electronic circuit as set forth in claim 1, wherein the clock rate of the clock signal (clk(t)) is set variably from a digital data stream which represents the instantaneous frequency of the input signal (x(t)).

4. An electronic circuit as set forth in claim 3, wherein the period duration and the amplitude of the input signal are represented digitally in the digital data stream.

5. An electronic circuit as set forth in claim 3 or claim 4, wherein there is provided a converter circuit which converts the analog input signal into a digital data stream before it is applied to the sigma-delta modulator (200) and the digital data stream produced in that way contains explicit information about the instantaneous frequency of the input signal.

6. An electronic circuit as set forth in claim 1, wherein the clock generator is so designed that an additional clock event is inserted upon a zero-crossing of the input signal.

7. An electronic circuit as set forth in claim 1, wherein the clock generator includes a plurality of delay elements which are arranged as a ring oscillator and the delay of which is adapted in response to the instantaneous frequency of the input signal, wherein the clock signal for the sigma-delta modulator is derived from the oscillator frequency of the ring oscillator.

8. An electronic circuit as set forth in claim 1, wherein the clock generator includes a clock divider which produces the clock for the sigma-delta modulator from a constant clock by division by a variable rational number, wherein the clock divider is determined in response to the instantaneous frequency of the input signal.

9. A method of operating a sigma-delta modulator comprising the steps of:
determining the instantaneous frequency of an input signal of the sigma-delta modulator, and
producing a clock signal for the sigma-delta modulator at a clock rate which is variably established in dependence on the instantaneous frequency of the input signal.

10. A method of designing an integrated circuit comprising the steps of:
arranging a sigma-delta modulator on an integrated circuit,
arranging a clock generator circuit for generating a clock signal on the integrated circuit; and
designing the clock generator circuit in such a way that in operation it generates a clock signal for the sigma-delta modulator which is at a clock rate which is variably adapted in response to the instantaneous input frequency of the input signal.
